(19) United States
(12) Patent Application Publication
(10) Pub. No.: US 2011/0215290 A1
(43) Pub. Date: Sep. 8, 2011

(54) ANTI-REFLECTED HIGH EFFICIENCY LIGHT EMITTING DIODE DEVICE

(76) Inventors: Pun-Jae Choi, Gyeonggi-do (KR); Jin-Soo Park, Gwangju (KR); Seong-Han Kim, Gyeonggi-do (KR); Myeong-Kook Gong, Gyeonggi-do (KR); Hyeon-Ryong Cho, Gyeonggi-do (KR)

(21) Appl. No.: 10/593,088

(22) PCT Filed: Jan. 7, 2005
(86) PCT No.: PCT/KR2005/000036

§ 371 Date: May 12, 2009

(30) Foreign Application Priority Data
Mar. 17, 2004 (KR) 10-2004-0018139

(51) Int. Cl. H01L 33/06

(52) U.S. Cl. 257/13; 257/E33.008

(57) ABSTRACT

The present invention is related to a light emitting diode device in which a fine prominence and depression is formed on a semiconductor layer to make an anti-reflection region. The light emitting diode device comprises, a substrate; a N-type semi-conductor layer; an active layer for generating light; P-type semiconductor layer; a first exposed region formed by etching the active layer and the P-type semiconductor layer to partly expose the N-type semiconductor layer; a first ohmic contact formed on the first exposed layer; a second ohmic contact formed on the P-type semiconductor layer, and having an opening to partly form a second exposed region on the P-type semiconductor layer, said second exposed layer being formed to partly have a ultra-fine prominence and depression.

### TECHNICAL FIELD

The present invention relates to a light emitting diode, and in particular, relates to an anti-reflected light emitting diode having an ultra-fine prominence and depression to increase a light extraction efficiency.

### BACKGROUND ART

Generally, a light emitting diode (hereafter referred as ‘LED’) is a kind of solid-state device for converting an electric energy to light, and have two semiconductor layers (N-type, and P-type) oppositely doped with each other and an active layer positioned between the layers. When a bias is applied to the two semiconductor layers, holes and electrons are injected into the active layer to be recombined to generate light. The light generated in the active region is omnidirectionally emitted, and a part of the light is emitted to the outside of semiconductor chip through a surface exposed to the outside.

Recently, as the material for semiconductor is improved, the efficiency of semi-conductor chip is also increased. New type LED is made of GaN group material to permit an efficient illumination in a spectrum from ultraviolet ray to green ray. As the LED is improved, the LED is expected to substitute prior art lighting used in a traffic signal lamp, an indoor or outdoor display, a headlight and a tail-light for vehicle, and prior art indoor lighting device. However, the prior art LED cannot emit all the light generated in the active layer. Thus, the efficiency is restricted.

FIG. 1 is a cross-sectional view of prior art light emitting diode provided with a mesh-type ohmic contact. After a N-type semiconductor layer 20, an active layer 30, and a P-type semiconductor layer 40 are in sequence deposited on a substrate 10, a mesh-type ohmic contact 50b is formed. The mesh-type is a structure having openings through which a part of the N-type semiconductor layer 40 is exposed. If, the ohmic electrode 50b having openings is not formed on the P-type semiconductor layer and, instead, a transparence metal (PT) is formed on the layer, a part of light generated in the active layer 30 is reflected at the P-type semiconductor layer 40 and the transparence metal. Even though a part of light is passed through the transparence metal, as the light is a degree of 400 nm of visual ray, a boundary condition is not satisfied in the thin transparence metal having a thickness of a few nm˜several tens nm to occur a loss of light. Therefore, by applying the ohmic electrode 50b having the openings, the light generated in the active layer is passed to the air through the openings, or through the openings and an epoxy resin to reduce the loss of light.

The LED provided with the ohmic electrode 50b has a problem. The typical refractive index of semiconductor material is about 2.2˜3.8, which is higher than that of the air (n=1.0) and encapsulating epoxy(n≈1.5). According to Snell's law, a light, with an angle larger than a critical angel, moved from a region with high refractive index to a region with low refractive index is not passed to the outside and is totally reflected to the inside (that is, Total Internal Reflection: TIR). Therefore, a part of light emitted from the active layer 30 cannot be passed through a surface, in contact with the air or the epoxy, of the P-type semiconductor layer 40 and is totally reflected to the inside at the surface. The reflected light continues reflections until absorbed in the LED, or is emitted to the outside through other surfaces. Thus, there is a problem that a light extraction efficiency is lowed in the light emitting diode with the mesh-type ohmic electrode.

### DISCLOSURE OF INVENTION

### Technical Solution

Therefore, an object of the present invention is to solve the problems involved in the prior art, and to provide a light emitting diode in which a light generated is not reflected from a semiconductor layer having an ultra-fine prominence and depression structure and is emitted to the outside to increase a light extraction efficiency.

According to one embodiment of the present invention, in a light emitting diode having a substrate, a N-type semiconductor layer, an active layer for generating light and a P-type semiconductor layer, the light emitting diode further comprises: a first exposed region formed by etching the active layer and the P-type semiconductor layer to partly expose the N-type semiconductor layer; a first ohmic electrode formed on the first exposed region; and a second ohmic electrode formed on the P-type semi-conductor layer, and having an opening to partly form a second exposed region on the P-type semiconductor layer. At least a part of the second exposed region is formed to have an ultra-fine prominence and depression.

Preferably, at least a part of the first exposed region excepting a portion having the first ohmic electrode has a prominence and depression structure.

According to other embodiment of the present invention, in a light emitting diode having a substrate, a N-type semiconductor layer, an active layer for generating light, a P-type semiconductor layer, a transparence metal (electrode), and a metal pad for wire bonding the light emitting diode further comprises: a first exposed region formed by etching the active layer and the P-type semiconductor layer to expose at least a part of the N-type semiconductor layer; and a first ohmic electrode formed on the first exposed region. At least a part of the first exposed region excepting a portion having the first ohmic electrode is formed to have an ultra-fine prominence and depression.

In the embodiments, the P-type semiconductor layer is preferably GaN doped with Mg the N-type semiconductor layer is preferably GaN doped with Si, and the active layer is preferably GaN.

In the embodiments, the ultra-fine prominence and depression is preferably a cluster of a cylinder shaped prominence and depression elements.

In the embodiments, the cylinder shaped prominence and depression element is substantially a cone type, a column type, or a cylinder having the depressed upper end.

In the embodiments, the width of the prominence and depression element is preferably 0.005˜3 μm, and more preferably 0.01˜0.5 μm. The height of the prominence and depression element is preferably 0.1˜1 μm, and more preferably 0.2˜7 μm.

In the embodiments, the width of the prominence and depression element is 0.01˜2 times larger than a peak wavelength of light emitted from the light emitting diode, and more preferably 0.1˜1 times larger. The height of the prominence and depression element is 0.5˜10 times larger than the peak wavelength of light emitted from the light emitting diode, and more preferably 1˜3 times larger.

In the embodiments, the density of the prominence and depression elements is preferably 1˜10000/μm², and more preferably 50˜500/μm².

According to the embodiments, the light extraction efficiency can be increased.

### DESCRIPTION OF DRAWINGS

The above objects, other features and advantages of the present invention will become more apparent by describing the preferred embodiment thereof with reference to the accompanying drawings, in which:

FIG. 1 is a cross-sectional view of prior art light emitting diode provided with a mesh-type ohmic contact;

FIG. 2 is a schematic perspective view of a light emitting diode according to one embodiment of the present invention;

FIG. 3 is a cross-sectional view taken along line S1 in FIG. 2;

FIG. 4 is a cross-sectional view of a light emitting diode according to other embodiment of the present invention;

FIG. 5 is a diagram showing various examples of a discrete prominence and depression element used in an ultra-fine prominence and depression structure formed on a light emitting diode according to the present invention;

FIG. 6 is an enlarged picture showing an ultra-fine prominence and depression structure of high density;

FIG. 7 is an enlarged picture showing an ultra-fine prominence and depression structure of low density;

FIG. 8 is an enlarged picture showing a thick ultra-fine prominence and depression structure;

FIG. 9 is an enlarged picture showing thin ultra-fine prominence and depression structure;

FIGS. 10 and 11 are schematic diagrams showing an ultra-fine prominence and depression structure formed on a light emitting diode according to the present invention; and

FIG. 12 is a graph illustrating the characteristic of optical power of a light emitting diode according to the present invention.

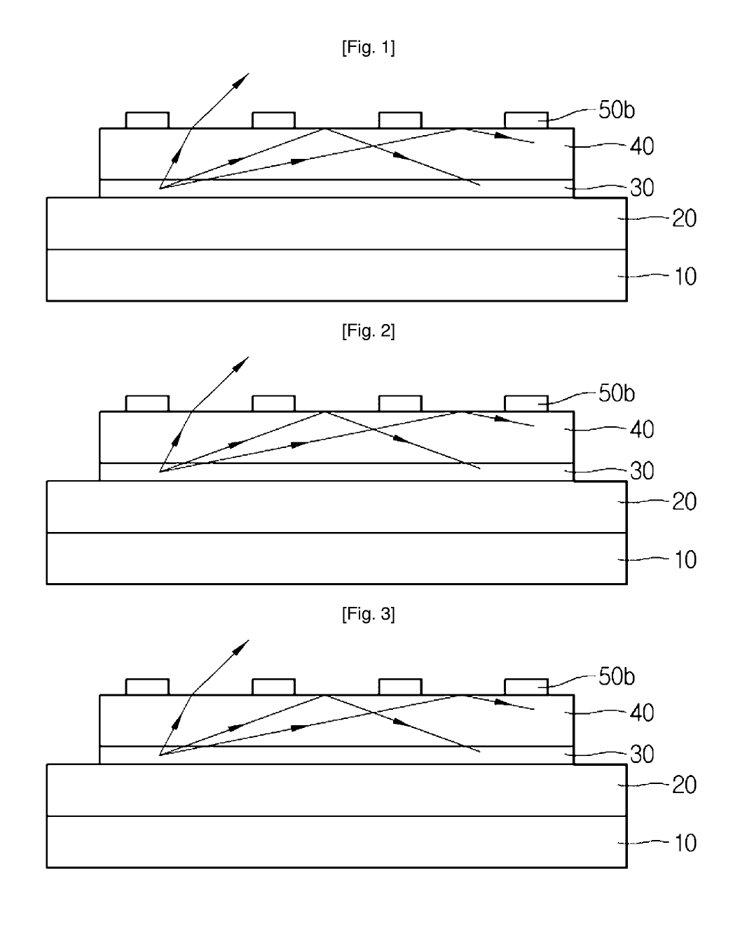

### BRIEF DESCRIPTION OF REFERENCE NUMBER

10: light-permeable sapphire substrate A1: first exposed region
20: N-type semiconductor layer A2: second exposed region
30: active layer 60: transparence metal
40: P-type semiconductor layer 70: metal pad for wire bonding
50a: first ohmic electrode 80: air
50b: second ohmic electrode

### BEST MODE

Reference will now be made in detail to an anti-reflected high efficiency light emitting diode device according to the present invention by using the accompanying drawings. In the following explanation, a description through accompanying drawings will be added in order to facilitate further complete understanding of the present invention, but it is apparent to those skilled in the art that the present invention can be carried out without a detailed description of the drawings. In cases, a description of the main elements or constituents of the known technology will be omitted if it obscures the point of the present invention unnecessarily. This is intended to avoid any possibility to obscure the description of the present invention.

FIG. 2 is a schematic perspective view of a light emitting diode according to one embodiment of the present invention, and FIG. 3 is a cross-sectional view taken along line S1 in FIG. 2.

With reference to FIG. 2 and FIG. 3, in order to realize the present invention, a N-type semiconductor layer 20, an active layer 30 and a P-type semiconductor 40 are in sequence formed on a substrate 10 by using an epitaxial process. The substrate 10 can be a light-permeable sapphire substrate. The N-type semiconductor layer 20 is formed by GaN (Gallium Nitride) doped with Si, but not restricted to the same. The P-type semiconductor layer 40 is formed by GaN doped with Mg but not restricted to the same. The active layer 30 formed by one selected from GaN, AlGaN and InGaN, and the amount of the Al and the In can be adjusted according to a kind of light generated in the active layer.

Next, a part of the active layer 30 and the P-type semiconductor layer 40 is etched by using a photo lithography process to expose the N-type semiconductor layer 20. Then, a first exposed region A1 is formed on the N-type semiconductor layer 20. Preferably, the first exposed region A1 is formed on the margin portions of the N-type semiconductor layer 20 by etching the edge portions of the active layer 30 and P-type semiconductor layer 40. Then, a first rectangular shaped ohmic electrode 50a is formed on one of the margin portions of the N-type semiconductor layer 20 by etching the active layer 30 and the P-type semiconductor layer 40.

Next, an ultra-fine prominence and depression structure is formed on the first exposed region A1 excepting the portion having the first ohmic electrode 50a, and on a second exposed region A2. The reason why the ultra-fine prominence and depression structure is formed is to emit the light generated in the active layer 30 to outside without a reflection in the first exposed region A1 and the second exposed region A2. The structure of prominence and depression and method for forming the same will be described later with reference to FIG. 5-FIG. 9. The second exposed region A2 is an exposed portion of the P-type semiconductor layer 40 excepting a portion having a second ohmic electrode 50b thereon. The exposed region includes portions exposed through openings of the second ohmic electrode 50b.

After forming the prominence and depression on the N- and the P-type semi-conductor layers, the first ohmic electrode 50a is formed on a part of the first exposed region A1, and the second ohmic electrode 50b is formed on the P-type semiconductor layer 40 through a photo lithography process.

As the ultra-fine prominence and depression structure is not formed under the first ohmic electrode 50a and the second ohmic electrode 50b, the under surfaces of the first and the second ohmic electrodes 50a and 50b maintain smoothness. The material for the ohmic electrodes 50a and 50b is selected from any one of Ti, Al, Au, Ni, Pt, Pd, Ag, Rh or compound of the elements. If a white metal such as Al, Pt and Cr is used, the reflexibility of the under surfaces can be increased.

In above description, the method for forming the ultra-fine prominence and depression structure on the N-type semiconductor layer 20 and the P-type semi-conductor layer 40 excepting the portions having the ohmic electrodes 50a and 50b thereon before forming the ohmic electrodes 50a and 50b. However, the ultra-fine prominence and depression structure can be formed on the N-type semiconductor layer 20 and the P-type semiconductor layer 40 excepting the portions having the ohmic electrodes 50a and 50b thereon after forming the ohmic electrodes 50a and 50b. In this case, the ohmic electrodes function as a self-aligner.

According to the embodiment, as the light generated in the active layer 30 is not reflected into the inside of the active layer by the ultra-fine prominence and depression structure which is formed on the first exposed region A1 excepting the portion having ohmic electrode 50a and on the second exposed regions A2, the light extraction efficiency of the light emitting diode is increased.

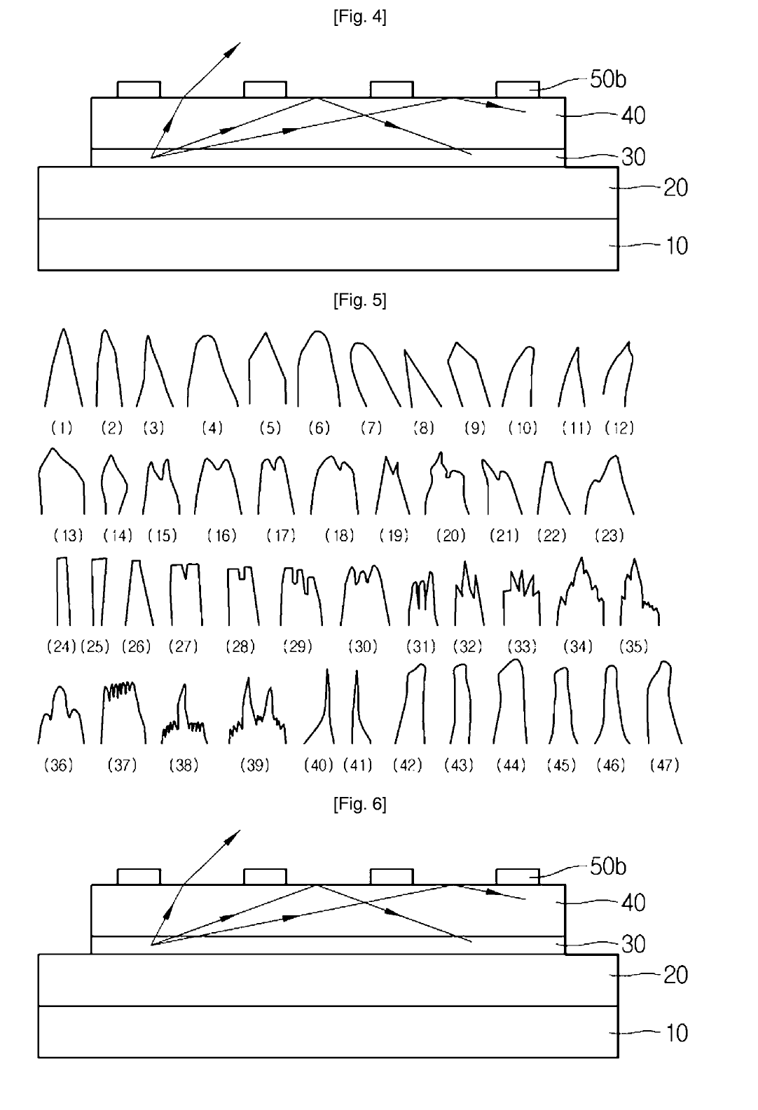

FIG. 4 is a cross-sectional view of a light emitting diode according to other embodiment of the present invention. When comparing the light emitting diode in FIG. 4 with that of FIG. 3, a ultra-fine prominence and depression structure is not formed on the P-type semiconductor layer, and a light permeable electrode (transparence metal) 60 and a metal pad 70 for wire bonding are instead formed on the P-type semi-conductor layer in FIG. 4. An ultra-fine prominence and depression structure is formed on the first exposed region A1 of the N-type semiconductor layer 20 excepting the portion having the ohmic electrode 50a as is in FIG. 3.

According to the embodiment, the light generated in the active layer, which is projected into the P-type semiconductor layer 40 with an incidence angle larger than a critical angle, is totally reflected to the inside by the light permeable electrode 60, and to be projected into the N-type semiconductor layer 20. The light projected into the N-type semiconductor layer is reflected actin at the bottom of the layer to be emitted to the outside of the layer through the exposed region A1 without a refection.

Further, in the embodiment, as the first ohmic electrode 50a is formed to have a smooth bottom surface as is in FIG. 3, the light projected to the bottom surface is reflected to the inside and emitted to the outside to increase the light extraction efficiency.

FIG. 5 is a diagram showing various example of a discrete prominence and depression element used in an ultra-fine prominence and depression structure formed on a light emitting diode according to the present invention.

The ultra-fine prominence and depression structure is a cluster of a cylinder shaped prominence and depression elements having a few ? (Angstrom)˜a few nm (nano-meter) dimensions. Each of the prominence and depression elements has a different size and shape. The width (w) of the discrete prominence and depression element is about 0.005˜3 μm, and preferably 0.01˜0.5 μm. The height of the discrete prominence and depression element is about 0.1˜1 μm, and preferably 0.2˜0.7 μm.

The dimension (width or height) of the prominence and depression element is similar to that of a peak wavelength (λp) of light generated in the light emitting diode. The width (w) of the prominence and depression element is 0.01˜2 times larger than the peak wavelength of light, and preferably 0.1˜1 times. The height of the prominence and depression element is 0.5˜10 times larger than the peak wavelength of light, and preferably 1˜3 times larger.

As shown in FIG. 5, the discrete prominence and depression element has various shapes. The shape of the element is generally a cylinder type protruded from the semi-conductor layers 20 and 40. More detail, the shape is similar to a cone or a column, or is a column having a depressed upper end. A small number of ruggedness˜tens of thousands of raggedness much smaller than the prominence and depression element can be formed on the depressed upper end.

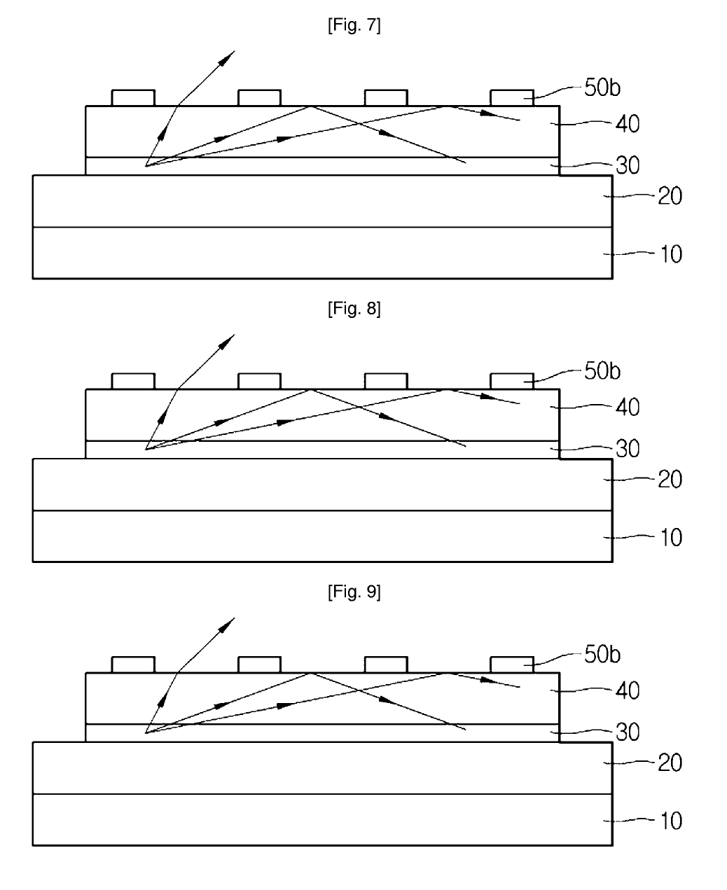

FIG. 6˜FIG. 9 are enlarged pictures showing a prominence and depression structure formed on a light emitting diode according to the present invention. FIG. 6 shows a prominence and depression structure of high density, FIG. 7 shows a prominence and depression structure of low density, FIG. 8 shows a thick prominence and depression structure, and FIG. 9 shows a thin prominence and depression structure.

The term ‘density’ used in here means the number of the prominence and depression element per the unit area [unit/μm]. The term ‘high density’ means that numbers of ruggedness are densely formed. The density of the prominence and depression elements is about 1˜10000/μm², and more preferably 50˜5000/μm².

The term ‘thick’ means that the height (h) is smaller than the width (w).

There are various methods for forming the prominence and depression structure on the semiconductor layers 20 and 40. In one method, a metal cluster is formed by depositing a metal (Ag Al, Au, Cr, In, Ir, Ni, Pd, Pb, Pt, Rd, Sn, Ti, W, or a compound of the elements) on the first exposed region A1 of the N-type semiconductor layer 20 and on the P-type semiconductor layer 40 and heat-treating the metal in high temperature. Next, the metal cluster in a portion to be formed with the first ohmic electrode 50a in the first exposed region and in a portion to be formed with the second ohmic electrode 50b in the P-type semiconductor layer 40 is removed by a photo lithography process. Next, the ultra-fine prominence and depression structure is formed by dry- or wet-etching the rest of metal cluster on the first exposed region A1 excepting the portion to be formed with the first ohmic electrode 50a and on the second exposed region A2.

In other method, the prominence and depression structure is formed by etching the first exposed region A1 excepting the portion to be formed with the first ohmic electrode 50a, and the second exposed region A2 using ICP and RIE through a photo lithography process, after growing roughly a silicon compound such as SiO₂ and S₃N₄ on the exposed regions by using a porous growing method.

Further, after growing silicon compound such as SO₂ and S₃N₄, and forming a metal cluster by depositing a metal (Ag Al, Au, Cr, In, Ir, Ni, Pd, Pb, Pt, Rd, Sn, Ti, W or a compound of elements) on the silicon compound and heat-treating the deposited metal in high temperature, the prominence and depression structure is formed by selectively (wet or dry) etching the metal cluster on the first exposed region A1 excepting the portion to be formed with the first ohmic electrode 50a, and the second exposed region A2 through a photo lithography process.

The examples for forming the prominence and depression structure on the semi-conductor layers 20 and 40 by using the methods are as follow.

### Example 1

### High Density, Thin Type

Type: Thin type (Width (w): about 0.01˜0.03 μm/Height (h): about 0.5 μm)

Density: about 40˜70/μm²

Used Metal: Ni, Au (20?-50?) (or In, Au and Ni compound used)

Heat treating: 550° C.˜650° C. for 60 sec ˜120 sec

Dry etching: ICP treating for 300 sec

### Example 2

### High Density, Thick Type

Type: Thick type (Width (w): about 0.08˜0.15 μm/Height (h): about 0.5 μm)

Density: about 40˜70/μm²

Used Metal: Ni, Au (50?-100?) (or In, Au and Ni compound used)

Heat treating: 550° C.˜650° C. for 60 sec ˜120 sec

Dry etching: ICP treating for 300 sec

### Example 3

### Low Density, Thin Type

Type: Thin type (Width (w): about 0.01˜0.03 μm/Height (h): about 0.5 μm)

Density: about 4˜8 μm²

Used Metal: Ni, Au (20?-50?) (or In, Au and Ni compound used)

Heat treating: 500° C.˜600° C. for 20 sec ˜30 sec

Dry etching: EP treating for 300 sec

### Example 1

### High Density, Thin Type, Low Height

Type: Thin type (Width (w): about 0.08˜0.15 μm/Height (h): about 0.3 μm)

Density: about 40˜70/μm²

Used Metal: Ni, Au (50?-100?) (or In, Au and Ni compound used)

Heat treating: 550° C.˜650° C. for 60 sec ˜120 sec

Dry etching: ICP treating for 300 sec

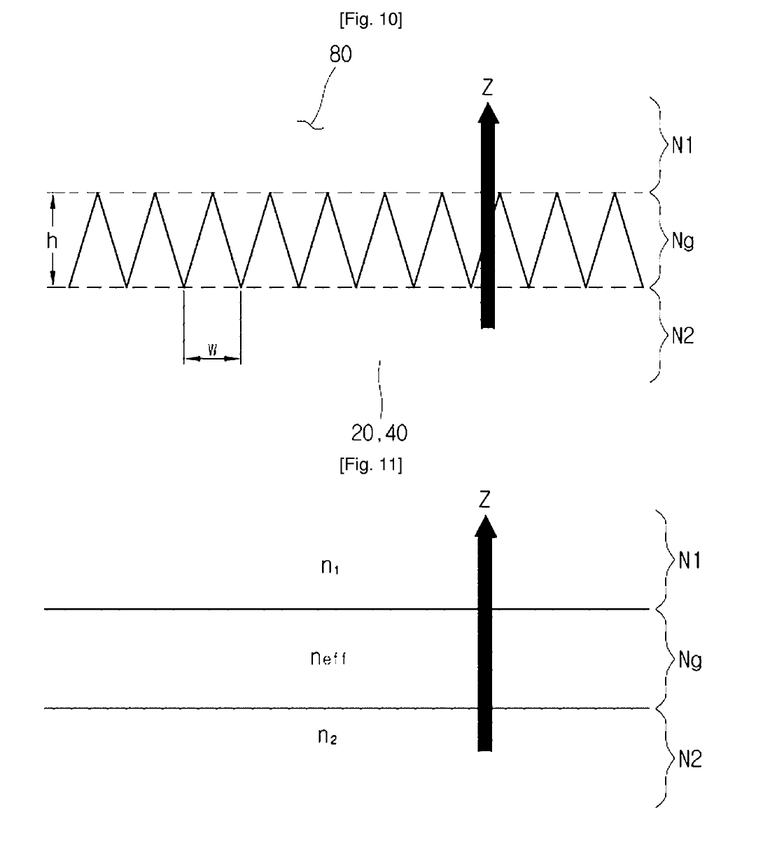

FIG. 10 and FIG. 11 are schematic diagrams showing an ultra-fine prominence and depression structure formed on a light emitting diode according to the present invention. With reference to FIG. 10a, there are three layers in the Fig. That is, a semi-conductor layer N2, an ultra-fine prominence and depression structure layer Ng and air layer are in the Fig. The ultra-fine prominence and depression structure is formed on the semiconductor layers 20 and 40, and the surface of the prominence and depression structure is in contact with air. The surface can also be in contact with an epoxy resin.

As described above, each of the prominence and depression elements making up the prominence and depression structure has a width of 0.01˜0.5 μm and a height of 0.2˜0.7 μm, which are about 0.1˜1 times larger than the peak wavelength (pλ).

If the dimensions (w, h) of the prominence and depression element making up the prominence and depression structure is made to have a value similar to a wavelength of light generated in the active layer, a refractive index n_{eff} of the ultra-fine prominence and depression structure is changed in linear from a refractive index n₂ of the semi-conductor layer N2 to a refractive index n₁ of the air layer N2. The semiconductor layer N2, the ultra-fine prominence and depression layer Ng and the air layer N1 can be conceptually represented as in FIG. 11.

As the refractive index is linearly changed along the arrow Z, discontinuity of refractive index, that is boundary, is not present. As the boundary is not present, TIR (Total Internal Reflection) phenomenon is not occurred at the boundary. In the result, as a reflection is not occurred in the ultra-fine prominence and depression layer Ng the ultra-fine prominence and depression layer Ng functions a Anti-reflection layer.

As the theoretical description for the light characteristic in case of a structure smaller than the wavelength of light being in a medium plane is disclosed in ‘The optical properties of artificial media structured at a subwavelength scale, Encyclopedia of Optical Engineering pp. 62-71, 2003’, detailed description will be omitted.

As the semiconductor layers 20 and 40 are treated to have the anti-reflection layer, all of light generated in the active layer is emitted from the semiconductor layers 20 and 40 to the outside to increase the light extraction efficiency.

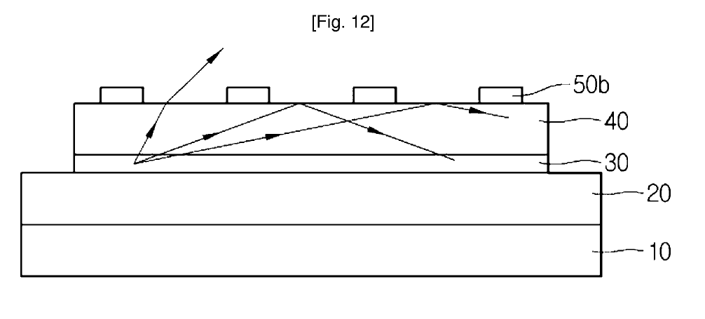

FIG. 12 is a graph illustrating the characteristic of optical power of the light emitting diode according to the present invention. As shown in FIG. 12, the optical power of the light emitting diode according to the present invention is much higher than that of prior art light emitting diode.

The optical power is different from embodiment to embodiment. As the height of the prominence and depression element and the density increase, the effect of the anti reflection can be increased.

While the present invention has been described and illustrated herein with reference to the preferred embodiments thereof, it will be apparent to those skilled in the art that various modifications and variations can be made therein without departing from the spirit and scope of the invention. Thus, it is intended that the present invention covers the modifications and variations of this invention that come within the scope of the appended claims and their equivalents.

### INDUSTRIAL APPLICABILITY

According to another aspect of the present invention, as the light extraction efficiency and the light generating efficiency are increased, a light emitting diode with high brightness can be fabricated.

According to other aspect of the present invention, a current supply can be smoothly done by employing a mesh-type ohmic contact having the opening to increase the light generating efficiency.

According to another aspect of the present invention, as the light extraction efficiency and the light generating efficiency are increased, a light emitting diode with high brightness can be fabricated.

1. A light emitting diode including a substrate, a N-type semiconductor layer, an active layer for generating light, and a P-type semiconductor layer, the light emitting diode comprising:
a first exposed region formed by etching the active layer and the P-type semiconductor layer to expose at least a part of the N-type semiconductor layer;
a first ohmic electrode formed on the first exposed layer;
a second ohmic electrode formed on the P-type semiconductor layer and having an opening at least a part of said P-type semiconductor layer having a second exposed region through said opening; and
said at least a part of P-type semiconductor layer being provided with an ultra-fine prominence and depression structure.

2. The light emitting diode as claimed in claim 1, wherein at least a part of the first exposed region excepting a portion having the first ohmic electrode has an ultra-fine prominence and depression structure.

3. A light emitting diode including a substrate, a N-type semiconductor layer, an active layer for generating light, a P-type semiconductor layer, a transparence metal (electrode), and a metal pad for wire bonding the light emitting diode comprising:
a first exposed region formed by etching the active layer and the P-type semiconductor layer to expose at least a part of the N-type semiconductor layer;
a first ohmic electrode formed on the first exposed layer; and
at least a part of said first exposed region excepting a portion having the first ohmic electrode being provided with an ultra-fine prominence and depression structure.

4. The light emitting diode as claimed in claim 1, wherein the P-type semiconductor layer is GaN doped with Mg the N-type semiconductor layer is GaN doped with Si, and the active layer is GaN.

5. The light emitting diode as claimed in claim 1, wherein the ultra-fine prominence and depression structure is a cluster of cylinder type prominence and depression elements.

6. The light emitting diode as claimed in claim 5, wherein the cylinder type prominence and depression element is a cone type, a column type, or a column type having a depressed upper end.

7. The light emitting diode as claimed in claim 5, wherein a width of the cylinder type prominence and depression element is 0.005˜3 μm, and a height is 0.1˜1 μm.

8. The light emitting diode as claimed in claim 5, wherein a width of the cylinder type prominence and depression element is 0.01˜0.5 μm, and a height is 0.2˜0.7 μm.

9. The light emitting diode as claimed in claim 5, wherein a width of the cylinder type prominence and depression element is 0.01˜2 times larger than a peak wavelength of the light emitting diode, and a height is 0.5˜10 times larger than the peak wavelength.

10. The light emitting diode as claimed in claim 5, wherein a width of the cylinder type prominence and depression element is 0.1˜1 times larger than a peak wavelength of the light emitting diode, and a height is 1˜3 times larger than the peak wavelength.

11. The light emitting diode as claimed in claim 5, wherein a density of the cylinder type prominence and depression elements is 1˜10000/μm².

12. The light emitting diode as claimed in claim 5, wherein a density of the cylinder type prominence and depression elements is 50˜500/μm².

13. The light emitting diode as claimed in claim 5, wherein the cylinder type prominence and depression element is formed by depositing a metal or silicon compound on the semiconductor layer, heat-treating the deposited metal or silicon compound, and dry- or wet-etching the deposited metal or silicon compound.

14. The light emitting diode as claimed in claim 13, wherein the metal is any one or combinations selected from a group of Ag Al, Au, Cr, In, Ni, Pd, Pt and Ti.

15. The light emitting diode as claimed in claim 13, wherein a temperature for the heat-treating is ranged from 90° C. to 400° C.

16. The light emitting diode as claimed in claim 15, wherein the cylinder type prominence and depression element is formed by selectivity, said selectivity being partly changed due to a reaction of the metal and the semiconductor at time of etching.
